(19) United States
(12) Patent Application Publication
(10) Pub. No.: US 2023/0257583 A1
(43) Pub. Date: Aug. 17, 2023

(54) RESIN COMPOSITION AND RESIN FILM, PREPREG, LAMINATED BOARD, COPPER-CLAD BOARD AND PRINTED CIRCUIT BOARD COMPRISING SAME

(71) Applicant: SHENGYI TECHNOLOGY CO., LTD., Guangdong (CN)

(72) Inventors: Guangbing CHEN, Guangdong (CN); Xianping ZENG, Guangdong (CN)

(21) Appl. No.: 18/009,156

(22) PCT Filed: Mar. 19, 2021
(86) PCT No.: PCT/CN2021/081660

§ 371 Date: Dec. 8, 2022

(30) Foreign Application Priority Data
Dec. 31, 2020 (CN) 202011626814.8

(51) Int. Cl. C08L 83/04; C08L 71/12; C08J 5/18; C08K 5/00; C08J 5/24

(52) U.S. Cl. CPC C08L 83/04; C08J 5/18; C08J 5/244; C08K 5/0066; C08L 71/12; C08J 2371/12; C08J 2383/07; C08L 2201/02; C08L 2203/20

(57) ABSTRACT

A resin composition, and a resin film, a prepreg, a laminated board, a copper-clad board, and a printed circuit board which comprise same. The resin composition comprises a combination of thermosetting polyphenylene ether resin, vinyl organic silicon resin, and a fully hydrogenated elastomeric polymer; and based on 100 parts by weight of the sum of the addition amounts of the thermosetting polyphenylene ether resin, the vinyl organic silicon resin, and the fully hydrogenated elastomeric polymer, the addition amount of the fully hydrogenated elastomer polymer is 20-50 parts by weight. The copper-clad board prepared from the resin composition has the characteristics of low dielectric constant, low dielectric loss, excellent thermal-oxidative aging resistance, high glass transition temperature, high heat resistance, high peel strength, low water absorption rate, and the like, and can be applied to scenes such as automobile radars in worse use environments.

### TECHNICAL FIELD

The present application relates to the technical field of communication materials, and especially, relates to a resin composition and a resin film, a prepreg, a laminate, a copper clad laminate and a printed circuit board comprising the same.

### BACKGROUND

For high-frequency electronic circuit base materials, it has great significance to maintain the stability of dielectric constant and dielectric loss of base materials during the long-term use for the variation in impedance performance of base materials and the signal integrity. In the base material resin curing system, the resin will undergo thermal-oxidative aging during the long-term use, and the dielectric constant and dielectric loss of the base material will increase, thereby affecting its stability and finally deteriorating the signal integrity of the base material. Therefore, an excellent thermal-oxidative aging resistance of the base material resin curing system is an important performance requirement for high-speed electronic circuit base materials.

The modified thermosetting polyphenylene ether resin contains lots of benzene rings in its molecular structure, and has no strong polar groups, which gives the polyphenylene ether resin excellent performances, such as high glass transition temperature, good dimensional stability, low thermal expansion coefficient, low water absorption rate, and especially, excellent low dielectric constant and low dielectric loss, allowing the modified thermosetting polyphenylene ether resin to be an ideal resin material for preparing high-speed circuit substrates.

CN105086417A discloses a resin composition, which includes: an unsaturated thermosetting modified polyphenylene ether resin and an MQ organic silicone resin which contains unsaturated double bonds, has a 3D network structure, and is formed by subjecting a monofunctional siloxane unit (M unit) and a tetrafunctional siloxane unit (Q unit) to hydrolysis and condensation. The high-frequency circuit substrate provided in this invention has high glass transition temperature, high thermal decomposition temperature, high interlayer adhesion, low dielectric constant and low dielectric loss tangent, which is very suitable as the circuit substrate for high-frequency electronics. The resin composition also has the problem of suffering aging by thermal oxidation easily.

Therefore, there is an urgent need in the art to develop a resin composition with low dielectric constant, low dielectric loss and excellent thermal-oxidative aging performance.

### SUMMARY

A first object of the present application is to provide a resin composition, in particular to provide a thermosetting resin composition used for copper clad laminates, and the board prepared from such resin composition not only has low dielectric constant (Dk) and dielectric loss (Df), but also has excellent thermal-oxidative aging resistance, which ensures that the dielectric constant and dielectric loss of the base material can remain stable during the long-term high-temperature use.

In order to achieve the object, the present application uses the technical solutions described below.

The present application provides a resin composition, and the resin composition includes: a thermosetting polyphenylene ether resin, a vinyl organic silicone resin and a fully hydrogenated elastomeric polymer; based on that a total addition amount of the thermosetting polyphenylene ether resin, the vinyl organic silicone resin and the fully hydrogenated elastomeric polymer is 100 parts by weight, an addition amount of the fully hydrogenated elastomeric polymer is 20-50 parts by weight, such as 22 parts by weight, 24 parts by weight, 26 parts by weight, 28 parts by weight, 30 parts by weight, 32 parts by weight, 34 parts by weight, 36 parts by weight, 38 parts by weight, 40 parts by weight, 42 parts by weight, 44 parts by weight, 46 parts by weight and 48 parts by weight.

In the present application, the fully hydrogenated elastomeric polymer is added to the system of thermosetting polyphenylene ether resin and vinyl organic silicone resin, and the fully hydrogenated elastomeric polymer has excellent low dielectric constant and low dielectric loss, and especially has excellent thermal-oxidative aging performance, thus effectively reduces Dk and Df of the resin system and improves the thermal-oxidative aging performance of Dk and Df at the same time, ensures that the base material is capable of possessing stable Dk and Df during the long-term high-temperature use, and also possesses high glass transition temperature, high heat resistance, high peel strength, low water absorption rate and other performances.

In the resin composition provided by the present application, the addition amount of the fully hydrogenated elastomeric polymer has a significant effect on the thermal-oxidative aging performance of the base material prepared from the resin composition, and based on that a total addition amount of the thermosetting polyphenylene ether resin, the vinyl organic silicone resin and the fully hydrogenated elastomeric polymer is 100 parts by weight, the addition amount of the fully hydrogenated elastomeric polymer is 20-50 parts by weight. When the addition amount of the fully hydrogenated elastomeric polymer is less than 20 parts by weight, the base material prepared from the resin composition will have relatively high Df and non-significant improvement in thermal-oxidative aging performance. When the addition amount of the fully hydrogenated elastomeric polymer is more than 50 parts by weight, the base material prepared from the resin composition will have excessively low glass transition temperature, causing hidden dangers to dimensional stability and heat resistant reliability.

In the present application, the fully hydrogenated elastomeric polymer with the addition amount selected from the above specific range ensures that the resin composition has low dielectric constant and low dielectric loss as well as excellent thermal-oxidative aging stability of dielectric constant and dielectric loss, and also has high glass transition temperature, high heat resistance, high peel strength, low water absorption rate and other performances, giving the copper clad laminate excellent comprehensive performances.

Preferably, the thermosetting polyphenylene ether resin is a modified thermosetting polyphenylene ether resin, preferably a vinyl group-modified thermosetting polyphenylene ether resin, and more preferably a methacrylate-modified thermosetting polyphenylene ether resin. In the present application, the “vinyl group” refers to a group containing a vinyl group.

Preferably, a number average molecular mass of the methacrylate-modified thermosetting polyphenylene ether resin is 500-10000 g/mol, such as 1000 g/mol, 2000 g/mol, 3000 g/mol, 4000 g/mol, 5000 g/mol, 6000 g/mol, 7000 g/mol, 8000 g/mol and 9000 g/mol, preferably 800-8000 g/mol, and more preferably 1000-4000 g/mol.

Unless otherwise specified, the number average molecular mass refers to a number average molecular mass measured by gel permeation chromatography in the present application.

Preferably, based on that a total addition amount of the thermosetting polyphenylene ether resin and the vinyl organic silicone resin is 100 parts by weight, an addition amount of the vinyl organic silicone resin is 20-60 parts by weight, such as 22 parts by weight, 25 parts by weight, 30 parts by weight, 35 parts by weight, 40 parts by weight, 45 parts by weight, 50 parts by weight, 55 parts by weight and 58 parts by weight.

Preferably, the vinyl organic silicone resin includes any one or a combination of at least two of a ring-structure vinyl organic silicone resin, a line-structure vinyl organic silicone resin or a 3D network-structure vinyl organic silicone resin.

Preferably, the fully hydrogenated elastomeric polymer includes a fully hydrogenated block elastomeric polymer.

Preferably, a raw material for preparing the fully hydrogenated block elastomeric polymer includes a combination of a vinyl aromatic compound and a conjugated diene.

Preferably, the vinyl aromatic compound includes any one or a combination of at least two of styrene, 3-methylstyrene, 4-methylstyrene, 3,5-diethylstyrene, 4-n-propylstyrene, α-methylstyrene, α-methylvinyltoluene, α-chlorostyrene, α-bromostyrene, dichlorostyrene, dibromostyrene or tetrachlorostyrene.

Preferably, the conjugated diene includes any one or a combination of at least two of 1,3-butadiene, 2-methyl-1,3-butadiene (isoprene), 2,3-dimethyl-1,3-butadiene or 1,3-pentadiene.

Preferably, the fully hydrogenated block elastomeric polymer is a linear block structure or a star block structure.

Preferably, the linear block structure is a diblock structure (A-B), a triblock structure (A-B-A or B-A-B), a tetrablock structure (A-B-A-B), a pentablock structure (A-B-A-B-A or B-A-B-A-B), or a structure having at least six blocks.

Preferably, the fully hydrogenated elastomeric polymer includes any one or a combination of at least two of a fully hydrogenated styrene-butadiene diblock copolymer, a fully hydrogenated styrene-butadiene-styrene triblock copolymer, a fully hydrogenated styrene-isoprene diblock copolymer or a fully hydrogenated styrene-isoprene-styrene triblock copolymer.

Preferably, the fully hydrogenated elastomeric polymer is a maleic anhydride-modified fully hydrogenated elastomeric polymer, and the fully hydrogenated elastomeric polymer is preferably selected from any one or a combination of at least two of a maleic anhydride-modified fully hydrogenated styrene-butadiene diblock copolymer, a maleic anhydride-modified fully hydrogenated styrene-butadiene-styrene triblock copolymer, a maleic anhydride-modified fully hydrogenated styrene-isoprene diblock copolymer or a maleic anhydride-modified fully hydrogenated styrene-isoprene-styrene triblock copolymer.

In the present application, the maleic anhydride-modified fully hydrogenated elastomeric polymer is further selected preferably, and since the maleic anhydride group is an oxygen-rich group, it can further improve the thermal-oxidative aging performance when used in the system of thermosetting polyphenylene ether resin and vinyl organic silicone resin.

In the present application, the maleic anhydride-modified fully hydrogenated elastomeric polymer is known in the art and can be purchased commercially, including but not limited to KIC1-023 from Kraton. Exemplarily, one of the synthetic processes of the maleic anhydride-modified fully hydrogenated elastomeric polymer includes that: a certain proportion of maleic anhydride monomers are added to the vinyl aromatic compound and conjugated diene monomers, and then the system is subjected to a catalytic hydrogenation process to realize full hydrogenation.

Preferably, in the maleic anhydride-modified fully hydrogenated elastomeric polymer, a content of the maleic anhydride group is less than or equal to 5%, such as 1%, 1.5%, 2%, 2.5%, 3%, 3.5%, 4% and 4.5%. In the present application, the “content of the maleic anhydride group” refers to a mass percentage of maleic anhydride monomers in the maleic anhydride-modified fully hydrogenated elastomeric polymer.

In the present application, the content of the maleic anhydride group is preferably less than or equal to 5%, and within such range, the obtained resin composition can have the best Df and thermal-oxidative aging performance. The excessively high content of the maleic anhydride group will lead to relatively high Df of the base material prepared from the resin composition.

Preferably, the resin composition further includes an initiator, and preferably a free radical initiator.

Preferably, the free radical initiator includes an organic peroxide initiator, and the free radical initiator is preferably selected from any one or a combination of at least two of dilauroyl peroxide, dibenzoyl peroxide, cumyl peroxyneodecanoate, tert-butyl peroxyneodecanoate, tert-pentyl peroxypivalate, tert-butyl peroxypivalate, tert-butyl peroxyisobutyrate, tert-butyl peroxy-3,5,5-trimethylhexanoate, tert-butyl peroxyacetate, tert-butyl peroxybenzoate, 1,1-bis(tert-butylperoxy)-3,5,5-trimethylcyclohexane, 1,1-bis(tert-butylperoxy)cyclohexane, 2,2-bis(tert-butylperoxy)butane, bis(4-tert-butylcyclohexyl)peroxydicarbonate, hexadecyl peroxydicarbonate, tetradecyl peroxydicarbonate, di-tert-pentyl peroxide, dicumyl peroxide, bis(tert-butylperoxyisopropyl)benzene, 2,5-dimethyl-2,5-di-tert-butylperoxyhexane, 2,5-dimethyl-2,5-di-tert-butylperoxyhexyne, diisopropylbenzene hydroperoxide, cumyl hydroperoxide, tert-pentyl hydroperoxide, tert-butyl hydroperoxide, tert-butyl cumyl peroxide, diisopropylbenzene hydroperoxide, tert-butyl peroxycarbonate-2-ethylhexanoate, tert-butyl peroxy-2-ethylhexyl carbonate, n-butyl-4,4-bis(tert-butylperoxy)valerate, methyl ethyl ketone peroxide or cyclohexane peroxide.

Preferably, based on that a total addition amount of the thermosetting polyphenylene ether resin and the vinyl organic silicone resin is 100 parts by weight, an addition amount of the initiator is 1-3 parts by weight, such as 1.5 parts by weight, 2 parts by weight, 2.5 parts by weight and 2.8 parts by weight.

Preferably, the resin composition further includes a flame retardant.

Preferably, the flame retardant includes a bromine-containing flame retardant and/or a phosphorus-containing flame retardant.

Preferably, based on that a total addition amount of the thermosetting polyphenylene ether resin, the vinyl organic silicone resin, the fully hydrogenated elastomeric polymer and the flame retardant is 100 parts by weight, an addition amount of the flame retardant is 10-30 parts by weight, such as 12 parts by weight, 15 parts by weight, 18 parts by weight, 20 parts by weight, 22 parts by weight, 24 parts by weight, 26 parts by weight and 28 parts by weight.

Preferably, the resin composition further includes a powder filler.

Preferably, the powder filler includes an organic filler and/or an inorganic filler.

Preferably, the inorganic filler includes any one or a combination of at least two of crystalline silica, fused silica, spherical silica, hollow silica, glass powder, aluminum nitride, boron nitride, silicon carbide, aluminum silicon carbide, aluminum hydroxide, magnesium hydroxide, titanium dioxide, strontium titanate, barium titanate, zinc oxide, zirconium oxide, aluminum oxide, beryllium oxide, magnesium oxide, barium sulfate, talc, clay, calcium silicate, calcium carbonate or mica.

Preferably, the organic filler includes any one or a combination of at least two of polytetrafluoroethylene powder, polyphenylene sulfide, polyetherimide, polyphenylene ether or polyethersulfone powder.

Based on that a total addition amount of the thermosetting polyphenylene ether resin, the vinyl organic silicone resin, the fully hydrogenated elastomeric polymer, the flame retardant and the powder filler is 100 parts by weight, an addition amount of the powder filler is 10-70 parts by weight, such as 15 parts by weight, 20 parts by weight, 25 parts by weight, 30 parts by weight, 35 parts by weight, 40 parts by weight, 45 parts by weight, 50 parts by weight, 55 parts by weight, 60 parts by weight and 65 parts by weight.

A second object of the present application is to provide a resin film, and the resin film is prepared by coating the resin composition according to the first object on a release material, subjecting the same to drying and/or semi-curing process, and then removing the release material.

A third object of the present application is to provide a prepreg, and the prepreg includes a reinforcing material and the resin composition according to the first object which is adhered to the reinforcing material after impregnating and drying.

In the present application, the reinforcing material can be organic fiber cloth, inorganic fiber woven or non-woven cloth; among them, the organic fiber cloth is aramid non-woven cloth; the inorganic fiber woven cloth is E-fiberglass cloth, D-fiberglass cloth, S-fiberglass cloth, T-fiberglass cloth, NE-fiberglass cloth or quartz cloth. A thickness of the reinforcing material is 0.01-0.2 mm, such as 0.02 mm, 0.05 mm, 0.08 mm, 0.1 mm, 0.12 mm, 0.15 mm and 0.18 mm. And the reinforcing material is preferably subjected to fiber splitting treatment as well as silane coupling agent surface treatment; the silane coupling agent is any one or a mixture of at least two of an epoxy silane coupling agent, an amino silane coupling agent or a vinyl silane coupling agent.

A fourth object of the present application is to provide a laminate, and the laminate includes at least one prepreg according to the third object.

Preferably, a preparation method of the laminate includes bonding one or more prepregs together by heating and pressing.

A fifth object of the present application is to provide a copper clad laminate, and the copper clad laminate includes at least one prepreg according to the third object and a metal foil covering on one or two sides of the at least one prepregs.

Preferably, the metal foil is a copper foil, a nickel foil, an aluminum foil or a steel use stainless (SUS) foil.

A sixth object of the present application is to provide a printed circuit board, and the printed circuit board includes the laminate according to the fourth object or the copper clad laminate according to the fifth object.

Compared with the prior art, the present application has the following beneficial effects:

In the present application, a specific amount of the fully hydrogenated elastomeric polymer is added to the system of thermosetting polyphenylene ether resin and vinyl organic silicone resin, which effectively reduces Dk and Df of the resin system and improves the thermal-oxidative aging stability of Dk and Df at the same time, ensuring that the base material is capable of possessing stable Dk and Df during the long-term high-temperature use. The prepared base material has low Dk / Df and excellent thermal-oxidative aging stability of Dk / Df, and also high glass transition temperature, high heat resistance, high peel strength and low water absorption rate.

In a preferred technical solution of the present application, maleic anhydride is used to modify the fully hydrogenated elastomeric polymer, which can further improve the thermal-oxidative aging stability of Dk / Df, and by preferably selecting the content of maleic anhydride group to be less than or equal to 5%, the Df can be further reduced while the excellent thermal-oxidative aging performance is guaranteed.

For the copper clad laminate provided by the present application, Dk (10 GHz) is 2.5-3.5, Df (10 GHz) is 0.0018-0.0023, the glass transition temperature is 180-208° C., the time to delamination at 300° C. (T300) is more than 60 min, the water absorption rate is 0.09%, the absolute value of the variation in Dk is 0.02-0.04 at 125° C./30 days, and the absolute value of the variation in Df is 0.0003-0.0006 at 125° C./30 days.

### DETAILED DESCRIPTION

Technical solutions of the present application are further described below with reference to specific embodiments. Those skilled in the art should understand that the embodiments described herein are merely used for a better understanding of the present application and should not be construed as specific limitations on the present application.

Raw materials used for preparing high-speed electronic circuit base materials in the embodiments of the present application are shown in the following table:

TABLE 1

| | | |
|---|---|---|
| Manufacturer | Product Name or Grade | Material Description |
| Sabic | SA9000 (with a number average molecular mass of 1900) | Methyl methacrylate-modified thermosetting polyphenylene ether resin |
| Wuhan University Silicone | WD-V4 | Ring-structure vinyl organic silicone resin |
| Runhe Chemical | RH-Vi306 | Line-structure vinyl organic silicone resin |
| Hangzhou Silicon-based Materials | V08 | 3D network-structure vinyl organic silicone resin |
| Kraton | D1118 | Unhydrogenated SBS resin |
| Kraton | G1726 | Fully hydrogenated SBS resin |
| Kraton | KIC1-023 | Maleic anhydride-modified fully hydrogenated SBS resin (containing 2.0% of maleic anhydride) |
| Kraton | KIC1-025 | Maleic anhydride-modified fully hydrogenated SBS resin (containing 1.0% of maleic anhydride) |
| Self-prepared | SBS-A | Maleic anhydride-modified fully hydrogenated SBS resin (containing 4.8% of maleic anhydride) |
| Self-prepared | SBS-B | Maleic anhydride-modified fully hydrogenated SBS resin (containing 6.0% of maleic anhydride) |
| AkzoNobel | PERKADOX BC-FF | Dicumyl peroxide |
| AkzoNobel | TRIGONOX B | Di-tert-butyl peroxide |
| Jiangsu Lianrui | DQ 2028L | Fused silica powder |
| Albemarle America | BT-93W | Bromine-containing flame retardant |
| Albemarle America | XP-7866 | Phosphorus-containing flame retardant |
| Shanghai Honghe | Low Dk1035 fiberglass cloth | Fiberglass cloth |

In the above table, the preparation of the maleic anhydride-modified fully hydrogenated SBS-A resin (containing 4.8% of maleic anhydride) includes that:

5.04 g of maleic anhydride was added to 100 g of SBS block copolymer G1726 resin particles, and the resin was subjected to extrusion modification under 0.5 g of initiator BPO, so as to obtain the maleic anhydride-modified fully hydrogenated SBS-A resin, in which the content of maleic anhydride was 4.8%.

In the above table, the preparation of the maleic anhydride-modified fully hydrogenated SBS-B resin (containing 6.0% of maleic anhydride) includes that:

6.38 g of maleic anhydride was added to 100 g of SBS block copolymer G1726 resin particles, and the resin was subjected to extrusion modification under 0.5 g of initiator BPO, so as to obtain the maleic anhydride-modified fully hydrogenated SBS-B resin, in which the content of maleic anhydride was 6.0%.

### Examples 1-10

Resin compositions are prepared according to the components shown in Table 2, and copper clad laminate samples are prepared according to the following preparation method of the copper clad laminate:
(1) Various components of the resin composition were mixed uniformly in toluene with a prescribed amount, and dispersed uniformly at room temperature, so as to obtain a resin liquid; and
(2) The reinforcing material (Low Dk1035 fiberglass cloth) was impregnated by the resin liquid obtained in step (1), subjected to rollers for controlling the suitable mass per unit area, and dried in an oven to remove the toluene solvent, so as to obtain a 1035 prepreg. Two 1035 prepregs were stacked, provided with copper foils of HOZ thickness on the upper and lower sides, and subjected to vacuum lamination and curing for 120 min in a press at a curing pressure of 25 Kg/cm² and a curing temperature of 200° C., so as to obtain the copper clad laminate.

### Comparative Examples 1-8

Resin compositions are prepared according to the components shown in Table 3, and copper clad laminate samples are prepared according to the following preparation method of the copper clad laminate:
(1) Various components of the resin composition were mixed uniformly in toluene with a prescribed amount, and dispersed uniformly at room temperature, so as to obtain a resin liquid; and
(2) The reinforcing material (Low Dk1035 fiberglass cloth) was impregnated by the resin liquid obtained in step (1), subjected to rollers for controlling the suitable mass per unit area, and dried in an oven to remove the toluene solvent, so as to obtain a 1035 prepreg. Two 1035 prepregs were stacked, provided with copper foils of HOZ thickness on the upper and lower sides, and subjected to vacuum lamination and curing for 120 min in a press at a curing pressure of 25 Kg/cm² and a curing temperature of 200° C., so as to obtain the copper clad laminate.

### Performance Test

The following performance tests are carried out for the copper clad laminates obtained in the above examples and comparative examples:
(1) Dielectric constant and dielectric loss test: the SPDR (split post dielectric resonator) method was used for the test, and the test condition was A state and the frequency was 10 GHz.
(2) Glass transition temperature (Tg) test: the test was performed according to the DMA method specified in IPC-TM-650 2.4.24.
(3) T300 (with copper): with reference to IPC-TM-650 2.4.24.1, the board with copper foil was used for the test at a temperature of 300° C.
(4) Copper foil peel strength (PS) test: IPC-TM-650 2.4.8; copper foil peel resistance tester.
(5) Water absorption rate test: the test was performed according to IPC-TM-650 2.6.2.1 method.
(6) Aging resistance test: the board was baked in an oven at 125° C. for 30 days, and Dk / Df were measured before and after baking the board.

The results of the above performance test are shown in Tables 2 and 3.

TABLE 2

| Raw Materials and Performances | Example 1 | Example 2 | Example 3 | Example 4 | Example 5 | Example 6 | Example 7 | Example 8 | Example 9 |
|---|---|---|---|---|---|---|---|---|---|
| SA9000 | 75 | 75 | 75 | 75 | 75 | 75 | 80 | 70 | 50 |
| WD-V4 | 25 | 0 | 0 | 0 | 0 | 0 | 0 | 0 | 0 |
| RH-Vi306 | 0 | 25 | 0 | 0 | 0 | 0 | 0 | 0 | 0 |
| V08 | 0 | 0 | 25 | 25 | 25 | 25 | 20 | 30 | 50 |
| D1118 | 0 | 0 | 0 | 0 | 0 | 0 | 0 | 0 | 0 |
| G1726 | 40 | 0 | 0 | 0 | 0 | 0 | 0 | 0 | 0 |
| KIC1-023 | 0 | 40 | 0 | 0 | 70 | 100 | 30 | 60 | 90 |
| KIC1-025 | 0 | 0 | 40 | 0 | 0 | 0 | 0 | 0 | 0 |
| SBS-A | 0 | 0 | 0 | 40 | 0 | 0 | 0 | 0 | 0 |
| SBS-B | 0 | 0 | 0 | 0 | 0 | 0 | 0 | 0 | 0 |
| PERKADOX BC-FF | 0 | 0 | 0 | 0 | 0 | 0 | 0 | 0 | 0 |
| TRIGONOX B | 2.0 | 2.0 | 2.0 | 2.0 | 2.0 | 2.0 | 1.0 | 2.0 | 3.0 |
| BT-93W | 0 | 0 | 0 | 0 | 0 | 0 | 20 | 40 | 60 |
| XP-7866 | 0 | 0 | 0 | 0 | 0 | 0 | 0 | 0 | 0 |
| DQ 2028L | 0 | 0 | 0 | 0 | 0 | 0 | 60 | 160 | 250 |
| Dielectric constant (10 GHz) | 2.5 | 2.4 | 2.5 | 2.6 | 2.4 | 2.3 | 2.8 | 3.0 | 3.5 |
| Dielectric loss (10 GHz) | 0.0020 | 0.0022 | 0.0021 | 0.0023 | 0.0019 | 0.0018 | 0.0021 | 0.0020 | 0.0022 |
| Tg (°C) | 200 | 180 | 205 | 203 | 199 | 191 | 201 | 203 | 198 |
| T300 (min) | > 60 min | > 60 min | > 60 min | > 60 min | > 60 min | > 60 min | > 60 min | > 60 min | > 60 min |
| PS (N/mm) | 0.8 | 0.8 | 0.8 | 0.8 | 0.8 | 0.8 | 0.9 | 1.0 | 1.0 |
| Water absorption rate (%) | 0.09 | 0.09 | 0.09 | 0.09 | 0.09 | 0.09 | 0.09 | 0.09 | 0.09 |
| Thermal aging resistance 125° C./30 days increment of Dk | 0.03 | 0.03 | 0.04 | 0.02 | 0.03 | 0.03 | 0.03 | 0.03 | 0.02 |
| Thermal aging resistance 125° C./30 days increment of Df | 0.0006 | 0.0005 | 0.0004 | 0.0003 | 0.0004 | 0.0003 | 0.0005 | 0.0004 | 0.0005 |

TABLE 3

| Raw Materials and Performances | Example 10 | Compara tive Example 1 | Compara tive Example 2 | Compara tive Example 3 | Compara tive Example 4 | Compara tive Example 5 | Compara tive Example 6 | Compara tive Example 7 | Compara tive Example 8 |
|---|---|---|---|---|---|---|---|---|---|
| SA9000 | 75 | 75 | 75 | 75 | 75 | 75 | 75 | 75 | 75 |
| WD-V4 | 0 | 25 | 0 | 0 | 0 | 0 | 0 | 0 | 0 |
| RH-Vi306 | 0 | 0 | 25 | 0 | 0 | 0 | 0 | 0 | 0 |
| V08 | 25 | 0 | 0 | 25 | 25 | 25 | 25 | 25 | 25 |
| D1118 | 0 | 0 | 0 | 0 | 40 | 0 | 0 | 0 | 0 |
| G1726 | 0 | 0 | 0 | 0 | 0 | 10 | 20 | 122 | 150 |
| KIC1-023 | 0 | 0 | 0 | 0 | 0 | 0 | 0 | 0 | 0 |
| KIC1-025 | 0 | 0 | 0 | 0 | 0 | 0 | 0 | 0 | 0 |
| SBS-A | 0 | 0 | 0 | 0 | 0 | 0 | 0 | 0 | 0 |
| SBS-B | 40 | 0 | 0 | 0 | 0 | 0 | 0 | 0 | 0 |
| PERKADOX BC-FF | 0 | 0 | 0 | 0 | 0 | 0 | 0 | 0 | 0 |
| TRIGONOX B | 2.0 | 2.0 | 2.0 | 2.0 | 2.0 | 2.0 | 2.0 | 2.0 | 2.0 |
| BT-93W | 0 | 0 | 0 | 0 | 0 | 0 | 0 | 0 | 0 |
| XP-7866 | 0 | 0 | 0 | 0 | 0 | 0 | 0 | 0 | 0 |
| DQ 2028L | 0 | 0 | 0 | 0 | 0 | 0 | 0 | 0 | 0 |
| Dielectric constant (10 GHz) | 2.9 | 2.9 | 2.8 | 3.0 | 2.5 | 2.8 | 2.9 | 2.2 | 2.1 |
| Dielectric loss (10 GHz) | 0.0024 | 0.0028 | 0.0029 | 0.0028 | 0.0020 | 0.0027 | 0.0028 | 0.0017 | 0.0016 |
| Tg (°C) | 208 | 207 | 183 | 210 | 201 | 189 | 180 | 150 | 143 |
| T300 (min) | > 60 min | > 60 min | > 60 min | > 60 min | > 60 min | > 60 min | > 60 min | > 60 min | > 60 min |
| PS (N/mm) | 0.8 | 0.8 | 0.8 | 0.8 | 0.8 | 0.8 | 0.8 | 0.8 | 0.8 |
| Water absorption rate (%) | 0.12 | 0.09 | 0.09 | 0.09 | 0.09 | 0.09 | 0.09 | 0.09 | 0.09 |
| Thermal aging resistance 125° C./30 days increment of Dk | 0.02 | 0.05 | 0.05 | 0.04 | 0.03 | 0.03 | 0.02 | 0.03 | 0.02 |
| Thermal aging resistance 125° C./30 days increment of Df | 0.0002 | 0.0015 | 0.0016 | 0.0015 | 0.003 | 0.0015 | 0.0014 | 0.0003 | 0.0002 |

It can be seen from Tables 2 and 3 that the copper clad laminates, prepared by the resin composition provided in the present application which includes the thermosetting polyphenylene ether resin, the vinyl organic silicone resin and the fully hydrogenated elastomeric polymer, have excellent thermal-oxidative aging stability of dielectric constant and dielectric loss in addition to low dielectric constant and low dielectric loss, and also have high glass transition temperature, high heat resistance, high peel strength, low water absorption rate and other comprehensive performances.

By comparing Comparative Examples 1-3 with Examples 1-3, it can be seen that, for the resin system that includes the modified polyphenylene ether and vinyl organic silicone resin but includes no fully hydrogenated elastomeric resin (Comparative Examples 1-3), the dielectric loss of the base material is relatively high and reaches up to 0.0028-0.0029, and the thermal-oxidative aging performance of dielectric loss for the base material is poor, in which the dielectric loss increases by 0.0015-0.0016 after 30 days of thermal-oxidative aging at 125° C., which cannot meet the market demand.

By comparing Comparative Example 4 with Example 3, it can be seen that, when the unhydrogenated elastomeric polymer (Comparative Example 4) is used, the thermal-oxidative aging performance of dielectric loss for the base material is poor, in which the dielectric loss of the base material increases by 0.003 after 30 days of thermal-oxidative aging at 125° C., which cannot meet the market demand.

By comparing Comparative Examples 5-6 with Examples 2, 5 and 6, it can be seen that, when the addition amount of the fully hydrogenated elastomeric polymer is less than 20 parts by weight (based on that a total addition amount of the thermosetting polyphenylene ether resin, the vinyl organic silicone resin and the fully hydrogenated elastomeric polymer is 100 parts by weight) in Comparative Examples 5-6, the dielectric loss of the base material is relatively high and reaches up to 0.0027-0.0028, and the thermal-oxidative aging performance of dielectric loss for the base material is poor, in which the dielectric loss increases by 0.0014-0.0015 after 30 days of thermal-oxidative aging at 125° C., which cannot meet the market demand.

By comparing Comparative Examples 7-8 with Examples 2, 5 and 6, it can be seen that, when the addition amount of the fully hydrogenated elastomeric polymer is more than 50 parts by weight (based on that a total addition amount of the thermosetting polyphenylene ether resin, the vinyl organic silicone resin and the fully hydrogenated elastomeric polymer is 100 parts by weight) in Comparative Examples 7-8, the glass transition temperature of the base material is relatively low and reaches as low as 143-150° C., causing hidden dangers to dimensional stability and heat resistant reliability, which cannot meet the market demand.

By comparing Example 10 with Example 4, it can be seen that, when the content of maleic anhydride is 6.0% in the maleic anhydride-modified fully hydrogenated elastomeric resin (Example 10), the dielectric loss of the base material is relatively high, and the Df value is 0.0024, which proves that the dielectric loss of the base material can be further reduced in the present application while the excellent thermal-oxidative aging performance is guaranteed by preferably selecting a content of maleic anhydride to be less than or equal to 5%, so as to improve the comprehensive performance of the board.

The applicant has stated that although the detailed method of the present application is described through the above embodiments, the present application is not limited to the above detailed method, which means that the implementation of the present application does not necessarily depend on the above detailed method. It should be apparent to those skilled in the art that any improvements made to the present application, equivalent substitutions of various raw materials of the product, the addition of adjuvant ingredients, the selection of specific manners, etc., all fall within the protection scope and the disclosure scope of the present application.

What is claimed is:

1. A resin composition, comprising: a thermosetting polyphenylene ether resin, a vinyl organic silicone resin and a fully hydrogenated elastomeric polymer; based on that a total addition amount of the thermosetting polyphenylene ether resin, the vinyl organic silicone resin and the fully hydrogenated elastomeric polymer is 100 parts by weight, an addition amount of the fully hydrogenated elastomeric polymer is 20-50 parts by weight.

2. The resin composition according to claim 1, wherein the thermosetting polyphenylene ether resin is a vinyl group-modified thermosetting polyphenylene ether resin.

3. The resin composition according to claim 1, wherein, based on that a total addition amount of the thermosetting polyphenylene ether resin and the vinyl organic silicone resin is 100 parts by weight, an addition amount of the vinyl organic silicone resin is 20-60 parts by weight.

4. The resin composition according to claim 1, wherein the fully hydrogenated elastomeric polymer comprises a fully hydrogenated block elastomeric polymery.

5. The resin composition according to claim 1, wherein the resin composition further comprises an initiator, and preferably a free radical initiator.

6. A resin film, which is prepared by coating the resin composition according to claim 1 on a release material, subjecting the same to drying and/or semi-curing process, and then removing the release material.

7. A prepreg, comprising a reinforcing material and the resin composition according to claim 1 which is adhered to the reinforcing material after impregnating and drying.

8. A laminate, comprising at least one prepreg according to claim 7.

9. (canceled)

10. A printed circuit board, comprising the laminate according to claim 8.

11. The resin composition according to claims 1, wherein the vinyl organic silicone resin comprises any one or a combination of at least two of a ring-structure vinyl organic silicone resin, a line-structure vinyl organic silicone resin or a 3D network-structure vinyl organic silicone resin.

12. The resin composition according to claims 2, wherein the vinyl group-modified thermosetting polyphenylene ether resin is a methacrylate-modified thermosetting polyphenylene ether resin; a number average molecular mass of the methacrylate-modified thermosetting polyphenylene ether resin is 500-10000 g/mol.

13. The resin composition according to claims 5, based on that a total addition amount of the thermosetting polyphenylene ether resin and the vinyl organic silicone resin is 100 parts by weight, an addition amount of the initiator is 1-3 parts by weight.

14. The resin composition according to any one of claims 1, wherein the fully hydrogenated elastomeric polymer comprises any one or a combination of at least two of a fully hydrogenated styrene-butadiene diblock copolymer, a fully hydrogenated styrene-butadiene-styrene triblock copolymer, a fully hydrogenated styrene-isoprene diblock copolymer or a fully hydrogenated styrene-isoprene-styrene triblock copolymer.

15. The resin composition according to any one of claims 1, wherein the fully hydrogenated elastomeric polymer is a maleic anhydride-modified fully hydrogenated elastomeric polymer, and the maleic anhydride-modified fully hydrogenated elastomeric polymer is selected from any one or a combination of at least two of a maleic anhydride-modified fully hydrogenated styrene-butadiene diblock copolymer, a maleic anhydride-modified fully hydrogenated styrene-butadiene-styrene triblock copolymer, a maleic anhydride-modified fully hydrogenated styrene-isoprene diblock copolymer or a maleic anhydride-modified fully hydrogenated styrene-isoprene-styrene triblock copolymer.

16. The resin composition according to any one of claims 15, wherein in the maleic anhydride-modified fully hydrogenated elastomeric polymer, a content of the maleic anhydride group is less than or equal to 5%.

17. The resin composition according to any one of claims 1, wherein the resin composition further comprises a flame retardant.

18. The resin composition according to any one of claims 17, based on that a total addition amount of the thermosetting polyphenylene ether resin, the vinyl organic silicone resin, the fully hydrogenated elastomeric polymer and the flame retardant is 100 parts by weight, an addition amount of the flame retardant is 10-30 parts by weight.

19. The resin composition according to any one of claims 1, wherein the resin composition further comprises a powder filler.

20. The resin composition according to any one of claims 19, based on that a total addition amount of the thermosetting polyphenylene ether resin, the vinyl organic silicone resin, the fully hydrogenated elastomeric polymer, the flame retardant and the powder filler is 100 parts by weight, an addition amount of the powder filler is 10-70 parts by weight.
